(19) United States
(12) Patent Application Publication
(10) Pub. No.: US 2026/0107693 A1
(43) Pub. Date: Apr. 16, 2026

(54) Tri-layer Merged-element Transmon Qubit

(71) Applicants: IMEC VZW, Leuven (BE); Katholieke Universiteit Leuven, Leuven (BE)

(72) Inventors: Jaques Van Damme, Leuven (BE); Daniel Perez Lozano, Schaerbeek (BE); Tsvetan Ivanov, Heverlee (BE)

(21) Appl. No.: 19/349,440

(22) Filed: Oct. 3, 2025

(30) Foreign Application Priority Data
Oct. 15, 2024 (EP) 24206694.2

(51) Int. Cl. H10N 60/12; G06N 10/40; H01P 7/08; H10N 60/01; H10N 60/80

(52) U.S. Cl. CPC H10N 60/12; G06N 10/40; H01P 7/086; H10N 60/0912; H10N 60/805

(57) ABSTRACT

A quantum circuit and related manufacturing method are disclosed. The quantum circuit may comprise a vertical Josephson junction formed by a bottom electrode in a first superconducting material layer, a tunnel barrier, and a top electrode in a second superconducting material layer. A contact portion and a coupling portion of the bottom electrode may be located inside and outside the Josephson junction, respectively. A transmon qubit of the quantum circuit may comprise the Josephson junction and a shunt capacitor formed by the top electrode and the contact portion of the bottom electrode as capacitor plates. A readout circuit may be capacitively coupled to the bottom electrode through the coupling portion and may include a coupling head. The coupling portion may be fitted into a recessed portion of the coupling head. The top electrode may be configured as a floating electrode, not resistively coupled to the first superconducting material layer.

### CROSS-REFERENCE TO RELATED APPLICATIONS

The present application is a non-provisional patent application claiming priority to EP 24206694.2, filed on Oct. 15, 2024, the contents of which are hereby incorporated by reference.

### FIELD OF THE DISCLOSURE

The present disclosure relates to the field of superconducting quantum circuits, and more specifically to a tri-layer merged-element transmon qubit device.

### BACKGROUND

Exploiting the phenomena of quantum superimposition, interference and entanglement, quantum computers promise to solve complex computational problems far more efficiently than today's most powerful classical computers. Various scalable qubit implementations for accurate quantum computing are currently being explored but demand great efforts and are technologically challenging.

### SUMMARY

A potential approach to qubit implementations for quantum computing applications may involve superconducting circuits that include a Josephson junction.

A transmon is a superconducting qubit in which the Josephson junction is electrically connected in parallel with a shunt capacitor that has a large capacitance compared to the stray capacitance of the Josephson junction. This may result in superconducting qubits that are less sensitive to charge noise but preserve a sufficient degree of anharmonicity in the quantum states. Mostly present on surfaces and interfaces, material defects and imperfections may have an adverse effect on the quantum coherence properties of transmon qubits, which may be useful for high-fidelity quantum computing applications. To reduce their impact, the shunt capacitors of transmons may be realized as large coplanar devices. Unfortunately, this approach may lead to transmons qubits with large device footprints near to square millimeters, which may lack the required compactness for scaling to high areal density qubit processors.

The large external shunt capacitor may be replaced by the self-capacitance of the Josephson junction. The merged-element transmon qubit structure may be etched into a sputtered Nb/a-Si/Nb tri-layer and an Nb air bridge may be formed over the qubit device to electrically connect the qubit top electrode to ground. However, a protective amorphous dielectric filler material may be applied to the transmon qubit while forming the Nb air bridge and may be removed thereafter. This process may create new material defects and imperfections in and around the Josephson junction region, which may thereby cause the qubit device to perform poorly in terms of the achievable coherence times.

Therefore, there is a need for compact transmon qubit circuitry with improved coherence properties.

The present disclosure describes a transmon qubit with improved coherence properties. The present disclosure describes a quantum circuit comprising a vertical junction merged-element transmon qubit and a related manufacturing method in accordance with the claims.

In one aspect, the present disclosure relates to a quantum circuit that may comprise a vertical Josephson junction and a transmon qubit. The vertical Josephson junction may be formed over a substrate and comprises a bottom electrode, a tunnel barrier and a top electrode. A contact portion of the bottom electrode may be located inside the vertical Josephson junction, whereas a coupling portion of the bottom electrode may be located outside the vertical Josephson junction. The bottom electrode may be formed in a first superconducting material layer and the top electrode may be formed in a second superconducting material layer. The transmon qubit may comprise the vertical Josephson junction and a shunt capacitor which may be formed by overlapping portions of the top electrode and the bottom electrode within the vertical Josephson junction. A readout circuit, which may comprise a coupling head, may be capacitively coupled to the bottom electrode through the coupling portion. The coupling portion of the bottom electrode may be fitted into/engages a recess of the coupling head of the readout circuit. This may help establish in a non-contact manner interlocking of the bottom electrode coupling portion and the readout circuit coupling head, which may allow capacitive coupling between the bottom electrode and the readout circuit for qubit state measurement. The top electrode of the vertical Josephson junction may be configured as a floating electrode, not resistively coupled to the first superconducting material layer.

In embodiments, a vertical direction may be defined by the vertical Josephson junction, i.e. the contact portion of the bottom electrode, the tunnel barrier and the top electrode may be provided in different material layers that are stacked vertically.

In embodiments, the top electrode and the contact portion of the bottom electrode may act as opposite capacitor plates of the shunt capacitor of the transmon qubit. This may allow the reduction or cancellation of charge noise and may eliminate the need for an additional shunting capacitor, external to the Josephson junction.

In embodiments, the coupling portion of the bottom electrode may act as a coupling capacitor with respect to the coupling head portion of the readout circuit. In embodiments, the recess in the coupling head of the readout circuit may be formed as a receiving slot with respect to the coupling portion of the bottom electrode. This may improve capacitive coupling. Providing the bottom electrode with a dedicated coupling portion outside the Josephson junction may mean that the Josephson junction and the coupling to the readout circuit may be designed nearly independently, potentially, with less constraints and more design freedom. This also may allow improved capacitive coupling between the bottom electrode and the readout circuit to obtain stronger readout signals and may reduce parasitic capacitive coupling between the top electrode and the readout circuit.

In embodiments, the readout circuit may be configured for dispersive readout of the qubit state (e.g., configured to induce and detect a dispersive shift of the resonance frequency of a readout resonator coupled to the transmon qubit). Furthermore, the readout circuit may comprise a readout resonator. The readout resonator may be provided as a coplanar waveguide, which may be simple to realize with high quality factors, exhibits low dispersion and good broadband operation, may not suffer from uncontrolled stray inductances or capacitances, and may have a characteristic impedance value that can be controlled accurately. Readout resonator quality factors Q≥30000 and normalized dispersive shifts |χ|/κ>1.0 may be obtained (χ represents the amount of dispersive shift and κ is the linewidth of the readout resonator). For instance, transmon qubit state-dependent readout resonator dispersive shifts of the order of 100 kHz may be achieved, which may be compatible with readout resonator linewidths up to 100 kHz. The readout resonator may be formed in the first superconducting material layer. The impedance value of the readout resonator may be at least 100 Ohm. In embodiments, the readout circuit may further comprise a transmission line that is electrically (e.g. capacitively) coupled to the readout resonator. To simplify circuit fabrication, the transmission line may be formed in the first superconducting material layer too.

In embodiments, the readout circuit may be formed in the first superconducting material layer to achieve coplanar capacitive coupling with the bottom electrode via the coupling head portion of the readout circuit and the coupling portion of the bottom electrode.

In embodiments, the readout circuit may be used for driving the transmon qubit, e.g. act as a driving circuit relative to the transmon qubit. This means that transitions between quantum states of the transmon qubit and/or the preparation of the transmon qubit in a particular quantum state (which may be a quantum superimposition of ground state and first excited state) may be driven or caused by the application of respective electrical pulses or pulse sequences to the readout circuit. In alternative embodiments, a separate drive line may be provided in addition to the readout circuit. This drive line may be arranged to pass or have an end portion in close proximity to the transmon qubit. In such alternative embodiments, the bottom electrode may be configured to extend out of the Josephson junction region at more than just one location along the junction periphery, thus connecting the contact portion to the coupling portion (as before) and further to a driving portion. Similar to the coupling portion, the driving portion may include a finger-like, strip-like or multi-fingered structure to allow for strong capacitive coupling with the additional drive line. The drive line may include a complementary shaped terminal section for receiving the driving portion, e.g. resulting in an interlocking, contact-free configuration of the drive line and the driving portion of the bottom electrode similar to the interlocking, contact-free configuration of the readout circuit coupling head and the coupling portion of the bottom electrode. Moreover, the driving portion may be connected to the contact portion of the bottom electrode via a tapered section. The driving portion and the coupling portion may be connected and extend from opposite sides of the contact portion of the bottom electrode, or may be connected and extend at an angle, e.g. at a right angle, from the contact portion of the bottom electrode.

In embodiments, the bottom electrode coupling portion and the readout circuit coupling head can have complementary interlocking profiles, wherein the interlocking is loose and non-contact but includes a space between the two interlocking parts. The bottom electrode coupling portion may comprise or be formed as a prong, finger or tongue and the readout circuit coupling head may have a recess, slot or slit for receiving the corresponding prong, finger or tongue of the bottom electrode coupling portion, e.g. as in a flat or planar version of the mortise (cut-out) and tenon (tongue) interlocking profiles.

In embodiments, the quantum circuit may further comprise a ground contact region that may be arranged for capacitive coupling with the contact portion of the bottom electrode. The ground contact region may be arranged adjacent to but separately from the vertical Josephson junction.

In embodiments, the ground contact region may be formed in the first superconducting material layer. The ground contact region may be structured as a ground plane adjacent to the contact portion of the bottom electrode. In embodiments, the ground contact region (e.g. ground plane) may be useful for providing shielding and a voltage reference.

In embodiments, the ground contact region and the bottom electrode may be coplanar structures of the first superconducting material.

In embodiments, the ground contact region and the bottom electrode may be distanced from each other by a gap along each transverse direction, perpendicular to the vertical direction defined by the vertical Josephson junction. The dimensions of the gap may vary along the perimeter of the bottom electrode. The dimension of the gap may be smaller along the edge of the contact portion of the bottom electrode compared to the edge of the coupling portion. The dimension of the gap may increase between the contact portion and the coupling portion of the bottom electrode. The dimension of the gap may be constant along the perimeter of the contact portion of the bottom electrode, except for the connecting end of the contact portion that joins the coupling portion of the bottom electrode. Additionally, a vertical gap may separate the ground contact region and the bottom electrode along the vertical direction if the ground contact region is provided in a different material layer than the first superconducting material layer.

In embodiments, the ground contact region may be arranged distantly from the bottom electrode. This may mean that the ground contact region does not directly contact or abut on the contact portion of the bottom electrode. A gap may be formed in the plane of the first superconducting material layer which may separate the ground contact region from the bottom electrode. In embodiments, the coupling portion of the bottom electrode may be arranged more distantly from the ground contact region than the contact portion of the bottom electrode. A gap in the plane of the first superconducting material layer, separating the ground contact region from the bottom electrode, may be wider along a boundary or periphery of the contact portion of the bottom electrode than along a boundary or periphery of the coupling portion of the bottom electrode.

In other embodiments, the ground contact region may be formed in a third superconducting material layer atop or above the second superconducting material layer. That is, the third superconducting material layer may be in contact with/contiguous with/interfacing the second superconducting material layer or may be separated from the second superconducting material layer by one or more intermediate layers. The second superconducting material layer may be arranged between the first and the third superconducting material layer. The ground contact region may be formed in the third superconducting material layer adjacent to the top electrode but without being contiguous with or adjoining the top electrode. The ground contact region may be separated vertically (i.e. along a vertical direction of the Josephson junction) from top electrode by a height distance between the third and the second superconducting material layer and the ground contact region may be offset along a transverse direction (i.e. direction perpendicular to the vertical direction of the Josephson junction) relative to the top electrode. The offset along each transverse direction may be sufficiently large to obtain an overlap-free ground contact region which does not overlap with the top electrode in the second superconducting material layer below the third superconducting material layer. The ground contact region may be structured as a ground plane of the third superconducting material layer.

The presence of a gap between the ground contact region and the outer circumference of the Josephson junction may mean that the different components of the quantum circuit (transmon, ground contact, readout/drive) may be defined by (lithographic) patterning and selective removal of material (e.g. etching) from the different material layers of a prefabricated multilayered material stack or wafer. No additional functional layers for quantum circuit operation may be deposited or grown, which may include further processing or temperature treatment. This may limit the introduction or propagation of surface defects, thereby may improve the coherence properties of the quantum circuit. Moreover, the gap dimension may be optimized to obtain strong capacitive coupling between the top electrode of the Josephson junction and electrical ground, whereby the readout coupling strength may be improved.

Furthermore, a gap between the ground contact region and the outer circumference of the Josephson junction may extend through the interface between the bottom electrode and the substrate and partially into the substrate. A recessed portion may be defined on the upper surface of the substrate which coincides with the gapped region throughout the whole surface of the planar quantum circuit. Partially removing substrate material across the gap region may cause the bottom electrode, the coupling head and the readout resonator structure to be formed on and supported by pedestals of the substrate material. This may mean that a larger volume portion of the electric fringing field is present in the vacuum instead of the substrate dielectric, which may further reduce dielectric losses.

In embodiments, the contact portion of the bottom electrode may correspond to the junction-forming portion of the bottom electrode that is located inside the Josephson junction.

In embodiments, the top electrode of the Josephson junction may completely overlap with the contact portion of the bottom electrode provided below the top electrode.

In embodiments, the top electrode, the tunnel barrier and the contact portion of the bottom electrode of the vertical Josephson junction may have identical shapes or outlines.

In embodiments, the vertical projections of the individual perimeters (outer edge) of the top electrode and the tunnel barrier of the vertical Josephson junction onto a common plane may be aligned or coincide.

In embodiments, the vertical projections of the individual perimeters (outer edge) of the top electrode, the tunnel barrier and the contact portion of the bottom electrode of the vertical Josephson junction onto a common plane may coincide.

In embodiments, the adjacent sidewalls of the top electrode and the tunnel barrier of the vertical Josephson junction (e.g., walls whose surface normal may be substantially perpendicular to the vertical direction of the Josephson junction) may be contiguous with each other.

In embodiments, the outer sidewalls of adjacent ones of the top electrode, the tunnel barrier and the contact portion of the bottom electrode of the vertical Josephson junction (e.g., walls whose surface normal may be substantially perpendicular to the vertical direction of the Josephson junction) may be contiguous with each other.

In embodiments, the outer sidewalls of the top electrode, the tunnel barrier and the contact portion of the bottom electrode may be vertical sidewalls, i.e., straight sidewalls rising at ninety-degree angles relative to an upper planar surface of the underlying substrate. Nonetheless, it may be possible to implement outer sidewalls of the top electrode, the tunnel barrier and the contact portion of the bottom electrode that may be slightly sloped, e.g., oriented at 90°+/−20° relative to an upper planar surface of the underlying substrate.

In embodiments, the tunnel barrier may be arranged between the contact portion of the bottom electrode and the top electrode. The top electrode may be formed atop the bottom electrode and the tunnel barrier.

In embodiments, the contact portion of the bottom electrode may be covered by the tunnel barrier.

In embodiments, the tunnel barrier may be covered by the top electrode.

In embodiments, the bottom electrode may be in direct contact with or supported by the substrate.

In embodiments, the bottom electrode may be formed as a single connected structure in which the contact portion and the coupling portion are provided at opposite ends.

In embodiments, the contact portion of the bottom electrode may be directly connected to coupling portions of the bottom electrode. In other embodiments, the contact portion of the bottom electrode and the coupling portion of the bottom electrode may be connected through an intermediate connecting portion such as a tapered connecting portion of the bottom electrode.

In embodiments, the bottom electrode may comprise an intermediate portion for connecting the contact portion of the bottom electrode to the coupling portion of the bottom electrode. The intermediate portion of the bottom electrode may be located outside the vertical Josephson junction. The intermediate portion of the bottom electrode may be tapered.

In embodiments, the coupling portion of the bottom electrode may be shaped or contoured like a finger, tongue, prong or strip in the layer of the first superconducting material.

In embodiments, the coupling portion of the bottom electrode may correspond to an elongated strip or single-fingered coupling structure of the first superconducting material. In other embodiments, the coupling portion of the bottom electrode may correspond to an interdigitated multi-fingered coupling structure of the first superconducting material.

In embodiments, the coupling portion of the bottom electrode may extend along a preferential direction within the layer of the first superconducting material, e.g., may be shaped as a long and narrow piece of first superconducting material, whereby a width of the coupling portion is smaller than a length of the coupling portion. The width of the coupling portion may be larger than a (tip) width at the tip of the contact portion that is closest to the coupling portion.

In embodiments, an inner edge of the ground contact region may—without touching or intersecting—circumscribe, encircle or surround an outer edge of the contact portion of the bottom electrode in a top view of the quantum circuit. Similarly, a vertical projection of a boundary (perimeter, edge) of the ground contact region onto the plane of the first superconducting material layer may—without touching or intersecting—circumscribe, encircle or surround a boundary (perimeter, edge) of the contact portion of the bottom electrode.

In embodiments, an inner edge of the ground contact region may—without touching or intersecting—circumscribe, encircle or surround an outer edge of the top electrode in a top view of the quantum circuit, except for an end tip of the top electrode where the contact portion of the underlying bottom electrode may be transitioning towards or may be abutting the coupling portion of the bottom electrode. Similarly, a vertical projection of a boundary (perimeter, edge) of the ground contact region onto the plane of the second superconducting material layer may—without touching or intersecting—circumscribe, encircle or surround a boundary (perimeter, edge) of the top electrode, except for an end tip of the top electrode where the contact portion of the underlying bottom electrode may be transitioning towards or may be abutting the coupling portion of the bottom electrode.

In embodiments, an inner edge of the ground contact region may—without touching or intersecting—circumscribe, encircle or surround an outer edge or sidewall of the Josephson junction in a top view of the quantum circuit, except for an end tip of the Josephson junction where the contact portion of the bottom electrode may be transitioning towards or may be abutting the coupling portion of the bottom electrode.

In embodiments, an inner edge of the ground contact region may—without touching or intersecting—circumscribe, encircle or surround an outer edge or sidewall of the tunnel barrier in a top view of the quantum circuit, except for an end tip of the tunnel barrier where the contact portion of the bottom electrode may be transitioning towards or may be abutting the coupling portion of the bottom electrode. Similarly, a vertical projection of a boundary (perimeter, edge) of the ground contact region onto the plane containing the tunnel barrier may—without touching or intersecting—circumscribe, encircle or surround a boundary (perimeter, edge) of the tunnel barrier, except for an end tip of the tunnel barrier where the contact portion of the underlying bottom electrode may be transitioning towards or may be abutting the coupling portion of the bottom electrode.

In embodiments, the sidewalls or outer surfaces of the tunnel barrier of the Josephson junction may be interfacing air or vacuum or an inert gas.

In embodiments, the sidewalls or outer surfaces of the contact portion of the bottom electrode may be interfacing air or vacuum or an inert gas.

In embodiments, the sidewalls or outer surfaces of the bottom electrode may be interfacing air or vacuum or an inert gas.

In embodiments, the sidewalls or outer surfaces of the top electrode may be interfacing air or vacuum or an inert gas.

In merged-element transmon qubits, the electrical field may be confined to the junction region. Using air, vacuum or an inert gas as a surrounding medium that interfaces the sidewalls of the vertical Josephson junction instead of a dielectric filler or substrate material may avoid dielectric losses that may cause a decrease in the transmon qubit coherence times.

In embodiments, the vertical Josephson junction may be a tri-layer junction.

In embodiments, the tunnel barrier may be formed in a barrier layer. The first superconducting material layer, the barrier layer and the second superconducting material layer may be patterned layers of a tri-layer material stack. A tri-layer material stack may be prefabricated under optimized growth conditions for the different material layers, yielding high-quality and flat material layers even on wafer scale.

In embodiments, the barrier layer may be provided as an insulating material layer, e.g. as a dielectric layer. The dielectric layer may be a non-amorphous dielectric layer such as a crystalline dielectric layer. Non-amorphous tunnel barriers may reduce losses and improve the coherence properties of the qubit.

In embodiments, the top electrode may be free of resistive electrical contacts. The contact-free top electrode may be provided in a pristine condition. The pristine condition of the top electrode may include an outward upper surface, facing away from the tunnel barrier, which may be continuous and smooth and may not be interrupted by outwardly projecting structures. The upper surface may be free of any deposited metallic structures. Providing top electrodes without any resistive contacts may avoid the introduction of material defects and imperfections during contact formation.

In embodiments, the top electrode may have a smooth and continuous upper surface, which may be facing away from the tunnel barrier, and a lower surface that is facing the tunnel barrier. The upper surface of the top electrode may be a planar surface. The upper surface of the top electrode may interface with vacuum, air or a protective dielectric layer over its entire surface area.

In embodiments of the invention, the capacitance of the shunt capacitor of the transmon qubit may correspond to the self-capacitance of the vertical Josephson junction. This means that the transmon qubit may be of the merged-element type. Merged-element transmon qubits may have increased compactness and smaller footprints since they may not require electrical connection to large external capacitors.

In embodiments, the vertical Josephson junction may have a junction length along a first direction parallel to the substrate and a junction width along a second direction parallel to the substrate, the second direction being perpendicular to the first direction, and the ratio of junction width to junction length may be at most 0.02.

In embodiments, the vertical Josephson junction may have a junction area of size ‘A’ and junction perimeter of length ‘P’ such that P²≥200*A.

In embodiments, the vertical Josephson junction may have an oblong shape of width ‘w’ and area ‘A’ and the gap separating the ground contact region and the vertical Josephson junction may have a gap width ‘G’, such that G*w²/A<1 nm.

In embodiments, one or both of the first and second superconducting material layer may comprise aluminum.

In embodiments, the tunnel barrier may be formed in a dielectric layer, such as one comprising aluminum oxide. Aluminum may be used as a superconductor and may be oxidized to form high quality tunnel barriers. High-purity aluminum may be obtained at wafer scale by epitaxial growth processes.

In embodiments, vertical sidewalls of the vertical Josephson junction may be free of deposited dielectric residuals.

In another aspect, the present invention may relate to a method of manufacturing a quantum circuit of the previous aspect. The method may comprise the steps of: providing a multilayer material stack comprising a first superconducting material, a dielectric layer and second superconducting material on a substrate; forming a bottom electrode in the first superconducting material, which comprises a contact portion and a coupling portion; forming a top electrode in the second superconducting material, which is configured as a floating electrode, not resistively coupled to the first superconducting material layer; forming a transmon qubit comprising a vertical Josephson junction and a shunt capacitor, wherein the vertical Josephson junction comprises the contact portion of the bottom electrode, a tunnel barrier formed in the dielectric layer and the top electrode, and the shunt capacitor comprises the top electrode and the contact portion of the bottom electrode as shunt capacitor plates; capacitively coupling a readout circuit to the bottom electrode, including interlocking without contacting the coupling portion of the bottom electrode and a recess formed in a coupling head of the readout circuit.

In embodiments, the method may further comprise the step of forming a ground contact region in the first superconducting material layer or in a third superconducting material layer atop the second superconducting material layer. The ground contact region may be formed adjacent to the vertical Josephson junction. The ground contact region may have the structure of a ground plane.

In embodiments, providing the multilayer material stack may comprise depositing the first superconducting material layer, the dielectric layer and the second superconducting material layer on the substrate. Additional material layers such as a third superconducting material layer, buffer layers or seed layers may be deposited, e.g., on the second superconducting material layer or between the substrate and the first superconducting material layer. The first superconducting material layer, second superconducting material layer, tunnel barrier layer and other optional layers may be provided as films of a multilayer stack, e.g., thin films of an epitaxial stack.

In embodiments, depositing the first superconducting material layer, second superconducting material layer and/or tunnel barrier layer may include epitaxially growing these layers, or depositing these layers by sputtering, vapor deposition or atomic layer deposition techniques. Depositing the dielectric layer for the tunnel barrier may comprise depositing and subsequently oxidizing a metal or semiconductor layer, which may correspond to a thickness portion of the first superconducting material layer.

In embodiments, forming the top electrode may comprise patterning, e.g., lithographically through a resist, and selectively removing material from the second superconducting material layer. Material from the dielectric layer may be selectively removed at the same time (e.g., same removal processing step) or immediately following the selective material removal from the second superconducting material layer. If material from the dielectric layer is selectively removed together with material from the second superconducting material layer, the same pattern definitions or patterning structures may be used. That is, a thickness portion of the dielectric layer, which may include the complete thickness of the dielectric layer, may be etched together with the second superconducting material layer, which has the advantage that structures such as the Josephson junction contour are aligned for the second superconducting material layer and the dielectric layer. This may avoid an additional lithographic alignment step.

In embodiments, the method may further comprise the step of forming the tunnel barrier. This may include patterning, e.g., lithographically through a resist, and selectively removing material from the dielectric layer.

In embodiments, forming the bottom electrode may comprise patterning, e.g., lithographically through a resist, and selectively removing material from the first superconducting material layer. Material from the underlying substrate may be selectively removed at the same time (e.g., same removal processing step) or immediately following the selective material removal from the first superconducting material layer. If material from the substrate is selectively removed together with material from the first superconducting material layer, the same pattern definitions or patterning structures may be used. That is, a thickness portion of the substrate may be etched together with the first superconducting material layer.

In other embodiments, forming the bottom electrode may comprise patterning, e.g., lithographically through a resist, and selectively removing material from the second superconducting material layer. The resulting pattern for the bottom electrode in the second superconducting material layer may be then transferred to the first superconducting material. This may include etching through a layer thickness associated with the second superconducting material layer and into the material layers below the second superconducting material layer, e.g., into the insulating barrier layer and further into the first superconducting material layer. The top electrode may then be formed by selectively removing the excess material in the second superconducting material layer that does not contribute or belong to the top electrode structure.

In embodiments, patterning the first superconducting material layer, the dielectric layer and/or the second material layer may include the steps of depositing a resist layer, exposing the resist layer to optical or e-beam irradiation to define regions to be etched in accordance with a lithographic pattern (e.g., mask pattern), and developing the resist to define openings in the resist corresponding to the regions to be etched.

In embodiments, the selective removal of material from the first superconducting material layer, the dielectric layer and/or the second material layer may include etching away the material of these layers, e.g., in regions not protected by a resist layer.

A floating tri-layer merged-element transmon may be fabricated from any superconductor-insulator-superconductor tri-layer stack with only two patterning steps and no further added material, which may promise to have little introduced material defects and increased qubit coherence. The Josephson junction may be kept in a pristine condition, which may improve the quality of the tunnel barrier.

The quantum circuit may serve as a vehicle for transmon qubit testing. The increased barrier sensitivity and the area insensitivity of transmon qubits may be leveraged to identify and characterize better performing Josephson junction material combinations (e.g., tri-layer stacks) and develop ways to reduce fabrication variability.

Non-oxide insulators may be used and tested as tunnel barriers.

The quantum circuits may be manufactured at large qubit densities on wafer scale and in a way that may be CMOS compatible. No angled shadow evaporation of Josephson junction material may be required. Moreover, no protective dielectric filler or spacer materials may be introduced during circuit fabrication, which may introduce additional interface defects along the Josephson junction sidewalls or are difficult to remove afterwards without damaging the junction.

The coupling between the transmon qubits and the readout circuit may be obtained by compact coupling structures, which may avoid the use of extended and narrow antenna-like coupling structures.

Particular aspects of the disclosure are set out in the accompanying independent and dependent claims. Features from the dependent claims may be combined with features of the independent claims and with features of other dependent claims as appropriate and not merely as explicitly set out in the claims.

For purposes of summarizing the disclosure, certain objects of the disclosure have been described herein above. Of course, it is to be understood that not necessarily all such objects may be achieved in accordance with any particular embodiment of the invention. Thus, for example, those skilled in the art will recognize that the invention may be embodied or carried out in a manner that achieves one object without necessarily achieving other objects as may be taught or suggested herein.

The above and other aspects of the invention will be apparent from and elucidated with reference to the embodiment(s) described hereinafter.

### BRIEF DESCRIPTION OF THE FIGURES

The above, as well as additional, features will be better understood through the following illustrative and non-limiting detailed description of example embodiments, with reference to the appended drawings.

FIG. 1 shows a top view illustrating a portion of a quantum circuit, according to example embodiments.

FIG. 2 shows an enlarged perspective view of the quantum circuit in FIG. 1, according to example embodiments.

FIG. 3 shows a cross-sectional view of the Josephson junction in the quantum circuit of FIG. 1, according to example embodiments.

FIG. 4 shows an electrical circuit diagram for the quantum circuit, according to example embodiments.

FIG. 5 illustrates the frequency-junction barrier thickness relationship for a merged-element transmon qubit, according to example embodiments.

FIG. 6 illustrates the combined impact of the circumferential gap width and the Josephson junction area aspect ratio on the coupling capacitance between the junction top electrode and the ground contact region, according to example embodiments.

FIG. 7 illustrates the combined impact of the circumferential gap width and the Josephson junction areal aspect ratio on the readout contrast, according to example embodiments.

FIG. 8 shows a top view illustrating a portion of a quantum circuit, according to example embodiments.

FIG. 9 shows a magnified view of the transmon qubit in the quantum circuit of FIG. 8, according to example embodiments.

FIG. 10 shows a cross-sectional view of a portion of the quantum circuit as shown in FIG. 8, according to example embodiments.

FIG. 11 illustrates steps of a method for manufacturing a quantum circuit, according to example embodiments.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to but does not preclude the presence or addition of one or more other features, integers, steps or components, or groups thereof. Thus, the scope of the expression “a device comprising means A and B” should not be limited to devices consisting only of components A and B.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment. Furthermore, the particular features, structures or characteristics may be combined in any suitable manner, as would be apparent to one of ordinary skill in the art from this disclosure, in one or more embodiments.

Similarly, it should be appreciated that in the description of exemplary embodiments, various features are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the disclosure requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment.

In the description provided herein, numerous specific details are set forth. However, it is understood that embodiments may be practiced without these specific details. In other instances, well-known methods, structures and techniques have not been shown in detail in order not to obscure an understanding of this description.

Hereinunder, a “tri-layer” transmon qubit, as commonly understood in the field, designates transmon qubits whose Josephson junction is etched into a pre-fabricated tri-layer material stack. This means that the tri-layer stack is deposited first and then etched into shape. Tri-layer transmon qubits are distinct from transmon qubits that have an overlap-type of Josephson junction, in which the bottom electrode is patterned first, the barrier layer and the top electrode layer are then deposited, followed by the etching of the top electrode structure. Moreover, tri-layer transmon qubits are also distinct from transmon qubits that have a “shadow evaporated” Josephson junction according to which the bottom electrode is first deposited under one angle, using a resist shadow mask, then partially oxidized to form the barrier layer, and finally covered by the top electrode structure that is deposited under another angle (all in-situ using the same resist pattern).

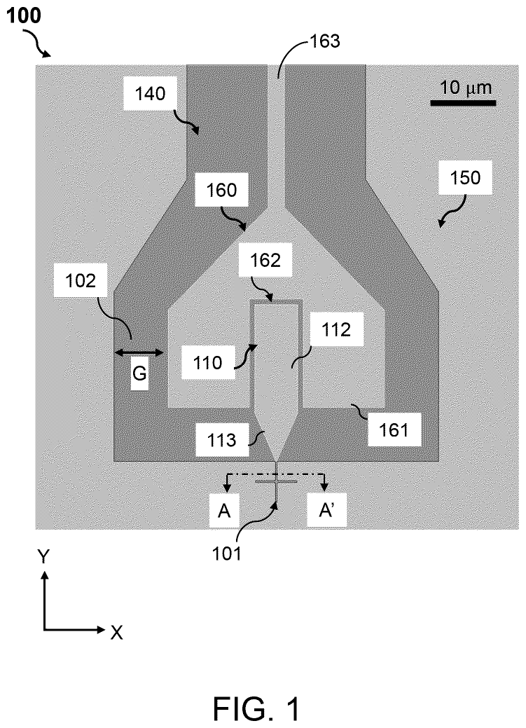

FIG. 1 shows a top view illustrating a portion of a quantum circuit 100, according to example embodiment. The quantum circuit 100 may comprise a transmon qubit structure with a cross-shaped, vertically oriented Josephson junction 101. Here, vertically oriented may mean that the Josephson junction is established along a vertical axis (e.g., the Z-axis) and the different junction material layers are stacked along this vertical axis. Moreover, the interfaces between adjacent materials of the Josephson junction and the resulting Josephson junction area may extend in a plane that is perpendicular to the vertical axis (e.g., the X-Y plane). A bottom electrode structure 110 of the quantum circuit may have a contact portion 111 that is located inside the Josephson junction 101 and a coupling portion 112 that may be located outside the Josephson junction 101. Hence, a part of the bottom electrode 110 may extend beyond and out of the junction region. The coupling portion 112 of the bottom electrode 110 may fit and extend into a corresponding recess 162 of a coupling head 161. A readout resonator structure 163, e.g., a coplanar waveguide structure, may include the coupling head 161 as an end portion, e.g., may be terminated by the coupling head 161 or may have one of its ends connected to the coupling head 161. Both the readout resonator structure 163 and the coupling head 161 may form part of a larger readout circuit 160. Although not shown, additional elements of the readout circuit 160 may be present in the quantum circuit, e.g., a Purcell filter, a transmission line or a feed line capacitively coupled to the readout resonator 163.

As shown, recess 162 may be formed as a receiving slot for coupling portion 112. The latter may exhibit a corresponding finger, prong or strip segment that suitably interlocks with the receiving slot in a non-contacting manner. Here, interlocking in a non-contact manner may mean that the coupling portion and the edge of the recess do not physically contact each other and, thus, may avoid a resistive connection, but may be separated by a narrow insulating space or gap. This may achieve good capacitive coupling between the coupling portion 112 and the coupling head 161 and hence between the bottom electrode 110 and readout resonator 163. The associated qubit-readout circuit coupling constant (coupling strength g/2π) may be about 3-10 MHz or larger, e.g., 3-50 MHz, for transmon qubit resonance frequencies in the range from 4 GHz to 10 GHz. Atomic layer deposition of the tunnel barrier layer may be used instead of sputter deposition if larger Josephson junction areas with thicker tunnel barriers are sought, which may achieve larger coupling strengths. In embodiments, the recess and coupling portion may be shaped and arranged in various other ways to interlock (without contacting each other) and provide good capacitive coupling.

The bottom electrode 110 may also include a tapered section 113 that is connected between the coupling portion 112 outside the Josephson junction 101 and the contact region 111 inside the Josephson junction 101. Alternatively, coupling portion 112 may include a taper 113 that connects the contact portion to the coupling portion of the bottom electrode. Taper 113 may ensure a smooth transition of the bottom electrode width (measured along the X-axis) from a narrower contact portion inside the Josephson junction 101 to a wider coupling portion outside the Josephson junction 101 and within the recess 162. A wider coupling portion of the bottom electrode outside the Josephson junction may increase the electrode surface area outside Josephson junction area, whereby stronger capacitive coupling between the bottom electrode and the readout circuit may be obtained, without unduly increasing the capacitive coupling between the bottom electrode and the ground contact region. A smooth transition may eliminate unwanted parasitic inductances or capacitances.

Spaced apart from the readout circuit 160, a ground contact region 150 may provide a reference voltage to the readout resonator 163 and coupling head 161, e.g., a ground (GND) signal. The ground contact region 150, which can be implemented as a ground plane, may extend from both sides of the readout resonator 163 and coupling head 161 towards the Josephson junction 101 and may wind around the periphery of the Josephson junction 101 to surround the Josephson junction by following its outer circumference (i.e., perimeter). The opposite electrodes (top and bottom) of the vertical Josephson junction may be both capacitively coupled to the ground plane 150. Good capacitive coupling between the top electrode of the Josephson junction 101 and the ground contact region 150 may be obtained by having the ground contact region almost completely enclose or encircle the Josephson junction area, except for a narrow space at the tip of the Josephson junction 101 where the contact portion 111 of the bottom electrode 110 connects to the coupling portion 112.

An insulating space 102—such as an air gap or vacuum gap—may extend between and separated the ground contact region 150 and the vertical Josephson junction 101 on the one hand and between the ground contact region 150 and the readout circuit 160 on the other hand. In the gapped region of quantum circuit 100, the bare substrate 140 may be exposed. Furthermore, the orientation and/or width dimension ‘G’ of gap 102 may be quasi constant locally but vary globally in the X-Y plane. For instance, the gap region between the edge of the Josephson junction 101 and ground plane 150 may be narrower (of smaller width) as compared to gap region between the coupling head 161 and the ground plane 150. The gap width may also increase along taper 113, starting from or close to the tip of Josephson junction. The gap width may be measured in a direction perpendicular to the gap-forming sidewalls (i.e., the surface-normal direction), whereas the gap orientation may be defined by curve of intersection between the substrate 140 plane and the lateral sidewalls of the ground contact region 150 interfacing the gap, or between the substrate 140 plane and the lateral sidewalls of the gap opposite to the sidewalls of the ground contact region, or a combination or average of both.

As shown, an inner edge or periphery of the ground contact region 150 and the outer edge or circumference of the Josephson junction 101 may have complementary shapes such that the Josephson junction 101 may be received or surrounded by a cavity-like planar indentation of the ground plane 150. Opposite sidewalls of the ground contact region 150 and the vertical Josephson junction may be facing each other and may be separated by gap 102, which may have a constant width ‘G’ along the perimeter of the Josephson junction 101.

The shape of the Josephson junction area, e.g., extending in the X-Y plane, may not be limited to cross-like contours. The Josephson junction area may have a rectangular, rounded rectangular, oblong, polygonal, ellipsoidal, comb-like, double-sided comb-like or star-like shape. The Josephson junction area shapes may be defined by a linear, possibly curved path in the X-Y plane or may include different branches. In some embodiments, the Josephson junction may be oblong, line-shaped or formed as a thin and narrow structure that extend along a particular axis, e.g., a longitudinal axis which may be parallel to one of the X-axis and Y-axis, or oriented at an angle relative to the Y-Axis. Moreover, the Josephson junction area may be convex and/or concave in shape.

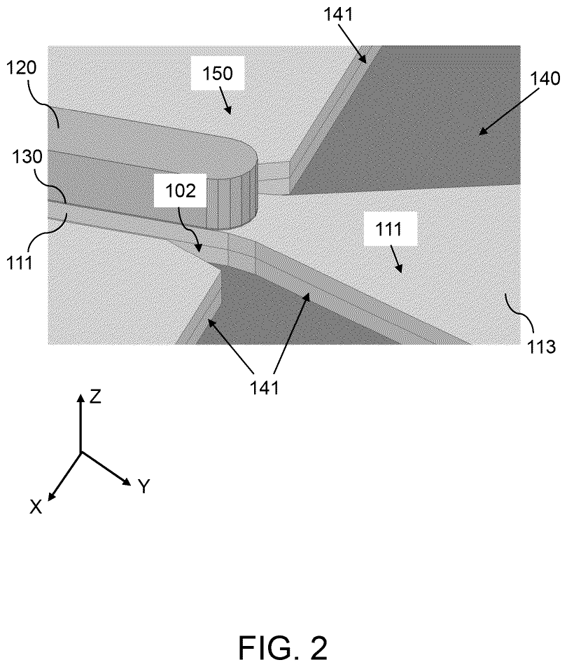

FIG. 2 shows an enlarged perspective view of the quantum circuit 100 in FIG. 1, according to example embodiments. FIG. 2 shows an enlarged perspective view of the Josephson junction 101 tip that may be pointing towards the coupling portion 112. The different vertically stacked layers that from the vertical Josephson junction 101 may be clearly distinguished. More specifically, the vertical Josephson junction 101 may comprise the contact portion 111 of the bottom electrode 110, a tunnel barrier 130 on top of the contact portion 111 and a top electrode 120 atop the tunnel barrier The contact portion 111 of the bottom electrode 110 may be located inside the Josephson junction 101 and the shape of the top electrode 120 may determine and delimit the Josephson junction area.

The planar shapes of the contact portion 111, the tunnel barrier 130 and the top electrode 120 may be substantially identical and horizontally aligned. This may mean that vertical projections of the respective edges of the contact portion 111, the tunnel barrier 130 and the top electrode 120 onto a common plane, e.g., a (bottom) plane of the substrate, may coincide almost everywhere, except for a possible deviation at the nose or tip of the Josephson junction where the contact portion 111 of the bottom electrode 110 joins the coupling portion 112. A possible deviation may be less than 5% of the total Josephson junction perimeter, e.g., less than 2% of the junction perimeter or less than 1% of the junction perimeter. Therefore, adjacent vertically extending sidewalls of the contact portion 111, the tunnel barrier 130 and the top electrode 120 may be contiguous with each other, except for the deviation at the nose or tip of the Josephson junction where the contact portion 111 of the bottom electrode 110 joins the coupling portion 112.

The quantum circuit 100 may comprise a transmon qubit of the merged-element type. This may mean that the inherent self-capacitance of the vertical Josephson junction 101 acts as a shunting capacitor of the transmon qubit. Under these circumstances, no external shunt capacitor may be implemented and connected to the vertical Josephson junction. This may enable reduced qubit device footprints and fabrication of higher area density quantum circuits containing the merged-element transmon qubits. The top electrode 120 and the contact portion 111 of the bottom electrode 110 may form the two opposite capacitor plates of the shunting capacitor of the transmon qubit. To achieve the good charge noise suppression behavior and anharmonicity typical of transmon qubits, the capacitor plates may be provided by the top electrode 120 and contact portion 111, and thus the resulting Josephson junction area, may be chosen to have larger areal size than in conventional superconducting qubit devices. For instance, top electrode and corresponding Josephson junction areas may be about at least 1 μm². Moreover, the top electrode may be devoid of any sharp edges along its circumference, e.g., be formed with rounded edges where the circumference of the top electrode changes direction or makes a turn. This may decrease coupling to potential local defects through excessively high electric fields.

Gap 102, e.g., comprising air or vacuum, may separate the vertical Josephson junction 101 from the adjacent ground contact region 150. The narrow gap 102 may enable capacitive coupling between the contact portion 111 of the bottom electrode 110 and the ground plane 150 as well as between the top electrode 120 and the ground plane 150 but may prevent avoiding a resistive short-circuit. As shown, the gap-forming sidewalls of the ground plane 150 may be flared towards the tapered section 113 of the bottom electrode 110, at the tip of the Josephson junction, to gradually increase the width of the gap 102 away from the Josephson junction. Furthermore, a lower portion of gap 102 may be formed inside the underlying substrate 140. That is, the gap 102 may extend through the interface between the bottom electrode 110 and the substrate 140 and partially into the substrate 140. For instance, the bottom wall of the gap 102 and a lower portion 141 of the vertical walls delimiting the gap 102 may be formed in the substrate 140. In this case, the lower vertically extending wall portions 141 may define a recessed portion on the upper surface of the substrate 140, which may coincide with the gapped region throughout the whole surface of the planar quantum circuit 100. Partially removing substrate material (e.g., substrate overetch) across the gap region 102 may cause the bottom electrode 110, the coupling head 161 and the readout resonator structure 163 to be formed on and supported by pedestals of the substrate material 140. This may result in a larger volume portion of the electric fringing field being present in the vacuum instead of the substrate dielectric, which may further reduce dielectric losses. Nonetheless, the bottom wall of gap 102 may correspond to the top surface of the substrate 140 in other embodiments, i.e., be located at the interface between the bottom electrode layer and the substrate underneath it.

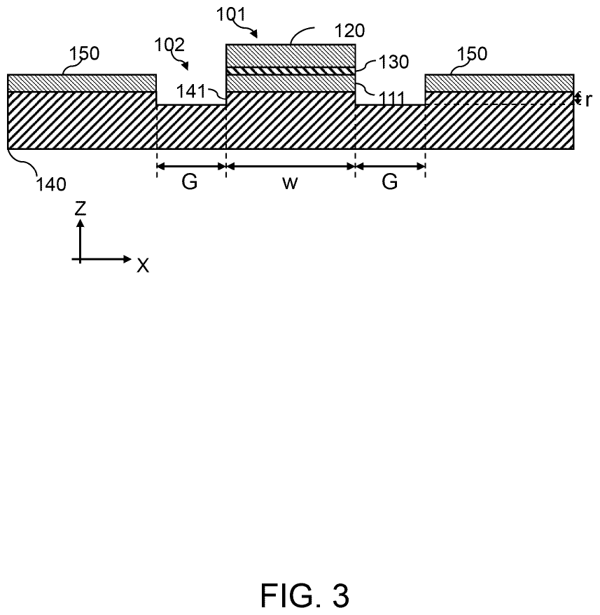

FIG. 3 shows a cross-sectional view of the Josephson junction 101 in the quantum circuit 100 of FIG. 1, according to example embodiments. FIG. 3 illustrates a of the Josephson junction 101 that is taken along the line AA′ in FIG. 1. As shown, the tri-layer Josephson junction 101 may be formed over substrate 140 and may be flanked, on both sides, by the ground contact region 150. The vertical sidewalls of the Josephson junction 101 and the ground contact region 150 may be separated by gap 102. The bottom electrode 110 with contact portion 111 and the ground contact region 150 may be separate coplanar structures that may have been formed in the same material layer. The top surfaces of the ground contact region 150 and the bottom electrode 110 may be located at the same vertical height (e.g., measured along the Z-axis).

A width of the vertical Josephson junction 101 in the X-direction may be about 100 nm or less. The gap 102 may have a width dimension of about 40 nm or less in the X-direction. The height or thickness of the bottom electrode 110 and the top electrode 120 in the Z-direction may be about 50 nm and 150 nm, respectively. The height or thickness of the tunnel barrier 130 in the Z-direction may be in the range of a few nanometers, e.g., 0.5-5.0 nm, or between 1.2-4.5 nm. Exemplary values for the Josephson junction area and related shunt capacitance may be 5.5 μm² and 125 fF for 4 nm thick ALD AlOₓ barriers and 1.7 μm² and 128 fF for 1.2 nm thick sputtered AlOₓ tunnel barriers, respectively. Superconducting bottom and top electrode may each comprise one of: Al, TiN, Nb, Ta, Mo, Pb, NbN, NbTiN. The tunnel barrier layer may include one of: AlOₓ, TaOₓ, Teflon, Si, GaN, SiC, SrTiO₃, LaAlO₃. The transmons qubits in accordance with the first embodiment may achieve energy ratios EJ/EC>50, resonance frequencies in the range 2-8 GHz and anharmonicity values (α/2π) above 100 MHz.

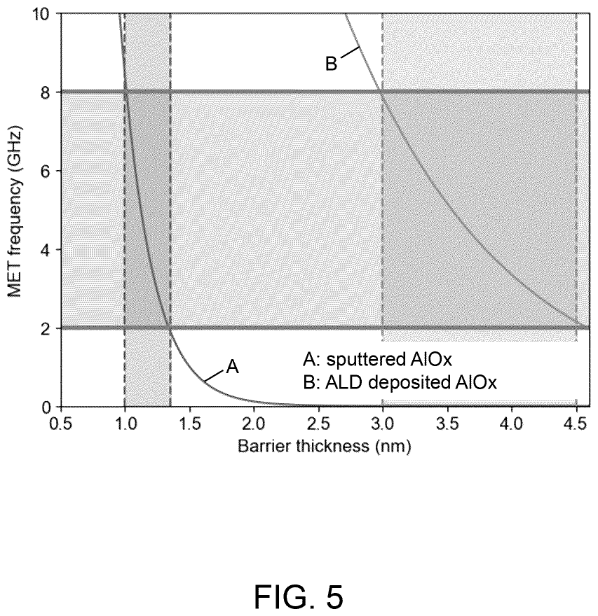

Furthermore, the resonance frequency of the floating merged-element transmon qubit, i.e., the qubit state transition frequency, may be independent of the Josephson junction area, e.g., the transmon qubit resonance frequency may be proportional to the expression sqrt(d*exp(−d)) with “d” being the tunnel barrier thickness. The dependence of the merged-element transmon (MET) qubit (resonance) frequency on the junction barrier thickness is graphically represented in FIG. 5.

FIG. 5 illustrates the frequency-junction barrier thickness relationship for a merged-element transmon qubit, according to example embodiments. FIG. 5 reveals the exponential decay of the MET qubit frequency with increasing barrier thicknesses for differently deposited aluminum oxide (AlOₓ) barrier materials, via sputter deposition and atomic layer deposition (ALD). This may indicate sensitivity of the MET qubit frequency with respect to the barrier thickness and the barrier deposition or formation method, which may improve the testing and characterization of different Josephson junction material combinations and manufacturing techniques. Typical MET qubit frequencies in the range 2-8 GHz are indicated by the rectangular window.

The bottom electrode 110, including the contact portion 111 and the coupling portion 112, the ground contact region 150 and the readout circuit 160, including the coupling head 161 and resonator structure 163, may be coplanar structures commonly formed in a first superconducting material layer over the substrate 140. The tunnel barrier 130 may be formed in an insulating barrier layer, e.g., dielectric material layer, between the first superconducting material layer and a second superconducting material layer. The top electrode 120 may be formed in the second superconducting material layer, on top of the barrier layer.

The first and second superconducting material layer may have the same composition and include the same superconducting material, e.g., aluminum. The barrier layer may comprise a non-amorphous dielectric material, e.g., non-amorphous aluminum oxide. Alternatively, the first and second superconducting material layer may each comprise one of: TiN, Nb, Ta, Mo, Pb, NbN, NbTiN. Other material choices for the tunnel barrier layer may include one of: tantalum oxide, Teflon, Si, GaN, SiC, SrTiO₃, LaAlO₃. It may be possible to provide a tunnel barrier layer which comprises or consists of an oxide of the superconducting metal of the first superconducting material layer. A suitable substrate material may be silicon, e.g., wafer-grade high-resistivity silicon, or sapphire.

Embodiments may not be limited to superconducting material layers of the same composition. For example, the first superconducting material layer may comprise one of TiN, Nb, Ta, Mo, Pb, NbN, NbTiN and Al, while the second superconducting material layer may comprise another one of TiN, Nb, Ta, Mo, Pb, NbN, NbTiN and Al.

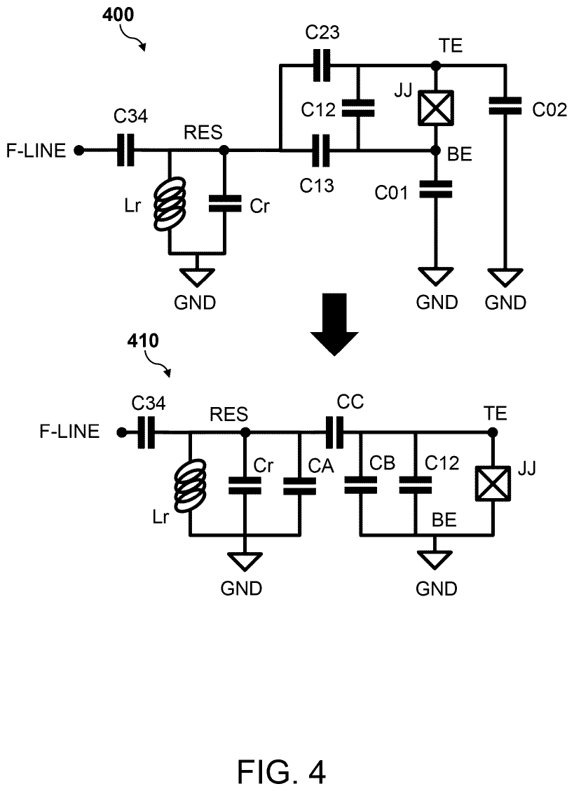

FIG. 4 shows an electrical circuit diagram 400 for the quantum circuit 100, according to example embodiments. FIG. 4 also illustrates a simplified version 410. A readout resonator (RES) composed of a capacitance (Cr) and an inductance (Lr) may be capacitively coupled—through capacitances C13 and C23—to the electrodes (bottom electrode BE, top electrode TE) of the Josephson junction (JJ) on the one side and is capacitively coupled—through capacitance C34—to a feedline (F-LINE) on the other side. A ground plane (GND) may provide the reference potential to the circuit. The top electrode (TE) and the bottom electrode (BE) may also be capacitively connected to the ground plane (GND) through the respective capacitances C01 and C02. The shunt capacitor inherent to the transmon qubit may be represented by the capacitance C12. Assuming a sufficiently small capacitive coupling between the top electrode (TE) and the readout resonator (RES), i.e., a capacitance C23 tending towards zero, the equivalent capacitances of the simplified circuit 410 are: CA≈(C01*C13)/(C01+C02+C13), CB≈(C01*C02)/(C01+C02+C13), and CC≈(C02*C13)/(C01+C02+C13).

In some embodiments, CA<<Cr and CB<<C12. Representing the coupling strength between the transmon qubit and the readout circuit, a large coupling capacitance “CC” may improve performance.

By providing the bottom electrode with the contact portion and the coupling portion as separate but connected parts, the capacitive coupling between the top electrode (TE) and the readout resonator (RES) may be reduced to a negligible amount while strong capacitive coupling between the bottom electrode (TE) and the readout resonator (RES) may be maintained. The coupling head for receiving the coupling portion of the bottom electrode may further increase the capacitive coupling between the bottom electrode (TE) and the readout resonator (RES). Moreover, a top electrode (TE) that has a long perimeter compared to a compactly designed junction, is thick in proportion to the bottom electrode, and is separated from the ground contact region by a relatively narrow gap (e.g., narrower than the Josephson junction width) may achieve stronger capacitive coupling to the ground contact region/ground plane. In consequence, a good coupling capacitance “CC” and corresponding coupling strength between the transmon qubit and the readout circuit may be realized in quantum circuits.

In some embodiments, the perimeter of the top electrode of the vertical Josephson junction may be increased by forming elongated or oblong Josephson junctions (e.g., strip-like, finger-like, or ellipsoidal junction area shapes) that have a small aspect ratio AR=w/L<<1.0, where ‘w’ refers to the characteristic junction width (e.g., along the X-axis) and ‘L’ refers to the characteristic junction length (e.g., measured along the Y-axis). For instance, one may constrain the aspect ratio to be AR≤0.02. The aspect ratio criterion notwithstanding, it may be possible to allow for different, e.g., non-oblong, area shapes of the Josephson junction and yet obtain long perimeters for the top electrode. An alternative design criterion for the vertical Josephson junction may be given as P²≥200*A, where ‘A’ designates the junction area and ‘P’ the junction perimeter or circumference. Moreover, good coupling strengths between the transmon qubit and the readout circuit may be achieved for gaps 102 surrounding the Josephson junction circumference, which obey the inequality G*w²/A<1 nm, where ‘G’ designates the characteristic gap width. There may be a tradeoff between Josephson junction area and transmon qubit anharmonicity at given tunnel barrier thickness (or the thereby determined qubit frequency). This may mean that good selectivity in the transitions between the qubit states (e.g., between the fundamental state, the first excited state, and the second excited state) may put a practical upper limit on the size of the Josephson junction area. Different tunnel barrier materials may exhibit different exponential scaling behavior of the resistance-area product as a function of the barrier thickness. Materials that benefit from a less pronounced thickness scaling in the resistance-area product may open the door to the design of even larger Josephson junction areas. The above-mentioned design criteria may be useful for the design of quantum circuits. Other design criteria may be developed and adhered to.

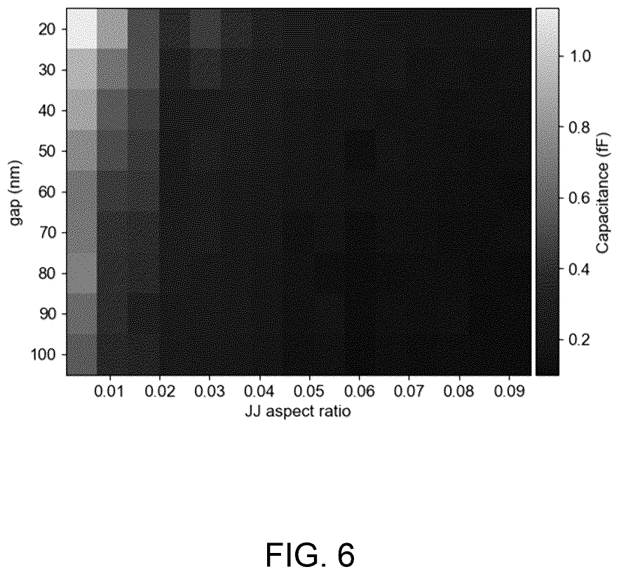

FIG. 6 illustrates the combined impact of the circumferential gap width and the Josephson junction area aspect ratio on the coupling capacitance between the junction top electrode and the ground contact region, according to example embodiments.

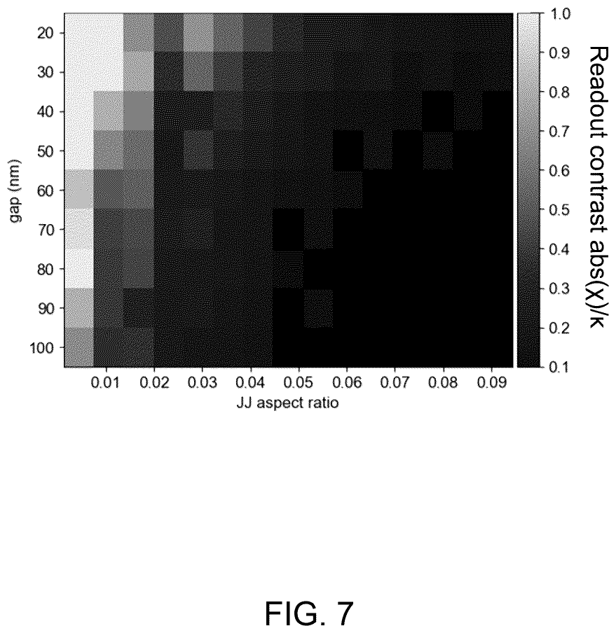

FIG. 7 illustrates the combined impact of the circumferential gap width and the Josephson junction areal aspect ratio on the readout contrast, according to example embodiments.

Together, FIG. 6 and FIG. 7 illustrate the combined impact of the width of the circumferential gap surrounding the vertical Josephson junction and the aspect ratio of the Josephson junction area on the coupling capacitance C02 between the junction top electrode and the ground contact region and the readout contrast |χ|/κ. Here, a vertically oriented Josephson junction with a sputter-deposited, 1.2 nm thick AlOₓ tunnel barrier and rounded rectangular shape may be assumed. The readout contrast may be indicative of the qubit state-dependent, dispersive shift in the readout resonator frequency. It may be understood from the figures that small circumferential gap widths/spacings below 100 nm, e.g., below 60 nm or less than 40 nm. Small aspect ratios of less than 0.02 may be used.

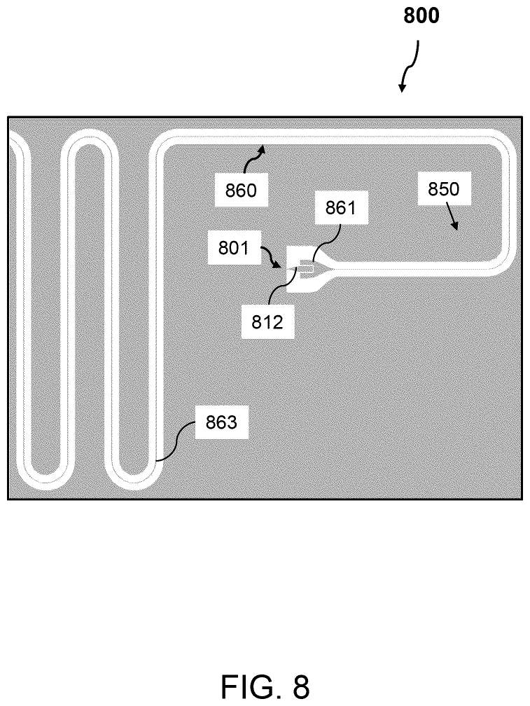

FIG. 8 shows a top view of a portion of a quantum circuit 800 which may include transmon qubit 801 with vertical Josephson junction, which may be coupled to a readout circuit 860. The bottom electrode of the transmon qubit 801 may include a coupling portion 812 that extends out of the Josephson junction region and into a complementarily shaped, recessed part of a coupling head 861. The planar readout circuit 860 may contain a readout resonator structure 863, e.g., a coplanar waveguide, which may be terminated by the coupling head 861. A portion of readout resonator 863 within the quantum circuit 800 is shown in FIG. 8. As can be seen, a ground contact region 850 may correspond to a large-area ground plane that may be common to the readout resonator 863 and the transmon qubit 801. The ground contact region 850, the readout resonator 863 with coupling head 861 and the bottom electrode with coupling portion 812 may be formed as coplanar structures with a same layer, e.g., a first superconductor containing layer.

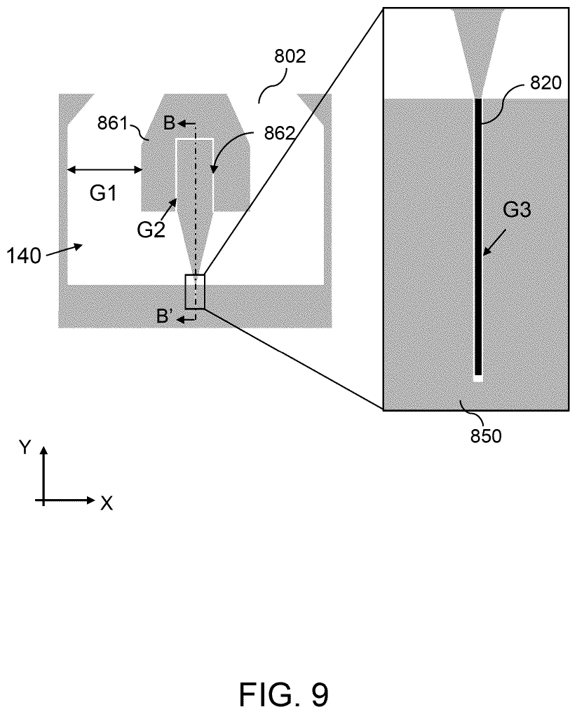

FIG. 9 shows a magnified view of the transmon qubit 801 in the quantum circuit 800 of FIG. 8, according to example embodiments. A gap region 802 of the planar quantum circuit 800 may delimit the ground plane 850 and may separate it from both the readout circuit 860 and the transmon qubit 801. Around the transmon qubit 801, e.g., adjacent to the periphery or outer sidewalls of the vertical Josephson junction, the gap region 802 may constitute a narrow circumferential space or non-conductive channel. This narrow circumferential space may widen to a broader channel at the extremity of the Josephson junction where the contact portion 811 of the bottom electrode 810 may abut the coupling portion 812. An associated gap dimension (e.g., gap width along the X-axis) may increase from G3 to G1. A second narrow circumferential space, e.g., having an associated gap dimension G2, may provide a corridor that connects to the broad trenches of the gap region extending from either side of the coupling portion 812 that may not be located inside the coupling head recess 862. The second narrow circumferential space may follow the edge of the coupling head recess 862 and may be wider than the first narrow circumferential space bordering the vertical Josephson junction sidewalls, i.e., G1>>G2>G3. This may reduce the capacitive coupling strength between the bottom electrode 810 and the ground contact region 850 but may strengthen the capacitive coupling between bottom electrode 810 and readout resonator 863 (via the interlocking coupling portion 812 and coupling head 861) and between transmon qubit top electrode 820 and ground contact region 850. In the gap region 802, the top surface of the underlying substrate 140 may be exposed.

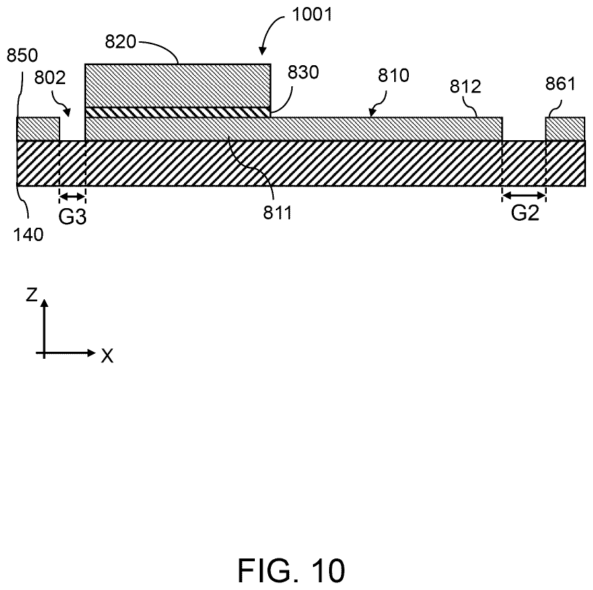

FIG. 10 shows a cross-sectional view of a portion of the quantum circuit 800 of FIG. 8, according to example embodiments. Specifically, FIG. 10 shows a cross-sectional view taken along the line BB′, which illustrates the different connected portions 811 and 812 of the bottom electrode 810, which may respectively be located inside and outside the vertical Josephson junction region 1001, as well as the gap spaces that may be of dimensions G2 and G3 that may separate the bottom electrode 810 from the coupling head 861 and the ground contact region 850 at each one of its respective ends. The quantum circuit 800 may not display substrate material removal across the gap region 802. This may mean that no vertical sidewalls may be formed in the underlying substrate 140 and exposed to the gap-filling medium (e.g., air or vacuum or inert gas). Furthermore, the bottom electrode 810, the coupling head 861 and the readout resonator structure 863 may not be formed on and supported by pedestals of the substrate material 140.

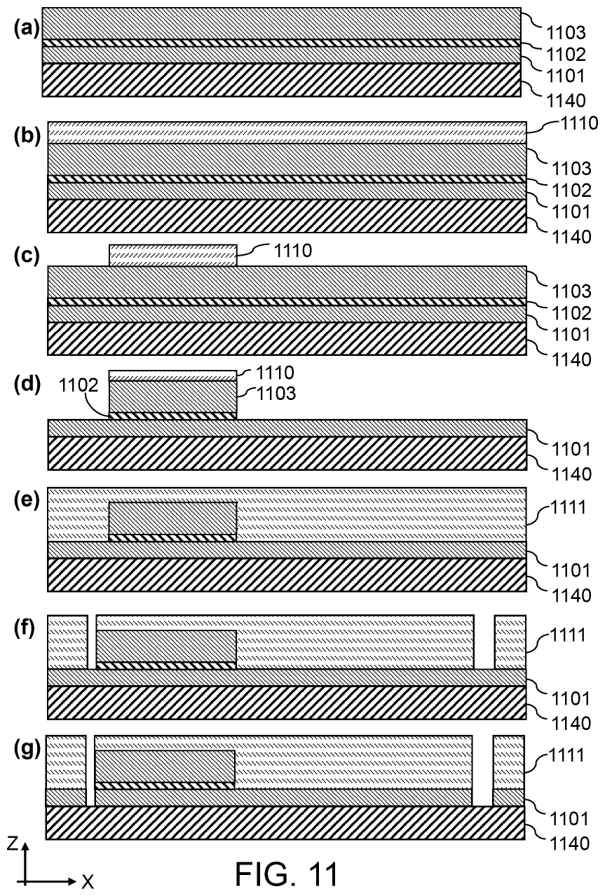

FIG. 11 illustrates steps of a method for manufacturing a quantum circuit, according to example embodiments. Specifically, FIG. 11 illustrates steps (a) through (f) of a method for manufacturing a quantum circuit. In a step (a), a multilayer stack is provided that may contain at least a first superconductor in a first layer 1101 formed on or over a substrate 1140, an insulator in a second layer 1102 formed on or over the first layer 1101, e.g., formed directly on and in physical contact with the first layer 1101, and a second superconductor in a third layer 1103 formed on or over the second layer 1102, e.g., formed directly on and in physical contact with the second layer 1102. The material or composition of the first and second superconductor may be identical, e.g., both comprising or consisting of one of Al, Ta, TiN, and Nb. Alternatively, the first and second superconductor may have different compositions. The insulator may be a dielectric material, e.g., comprising or consisting of AlOₓ, Teflon or TaOₓ. The substrate may comprise silicon, e.g., high-resistivity silicon. The multilayer stack may be provided on a wafer, e.g., in a wafer-scale manufacturing method. Providing the multilayer stack may include the preceding steps of depositing the first layer comprising the first superconductor (e.g., a thin film) on or over the substrate, depositing or forming the second layer comprising the insulator (e.g., a thin film) on or over the first layer, and depositing the third layer comprising the second superconductor (e.g. a thin film) on or over the second layer. The multilayer stack may be provided as an epitaxial stack. In embodiments, depositing the first and third layer, respectively comprising the first and second superconductor, may include layer deposition by sputtering techniques, atomic layer deposition (ALD) or suitable epitaxial stack-growing techniques. Forming the second layer comprising the insulator may comprise partially oxidizing an upper portion of the first layer, e.g. in a controlled ambient atmosphere.

A photoresist 1110 may be applied to the material layer stack in step (b) and may be lithographically patterned in step (c) to define the structure for the top electrode of the transmon qubit. Lithographic patterning may include exposing the photoresist layer 1110 to irradiation through an exposure mask or sequence of masks, or exposing the photoresist layer 1110 to focused irradiation that is scanned across the photoresists layer. The photoresist may be sensitive to the irradiation used for exposure, which may be optical or electron beam radiation. The choice of resist tonality and corresponding mask design (inverse or not) is non-limiting, but a negative resist may be used in embodiments that use e-beam writing techniques for lithography, whereby writing/exposure times may be reduced. Lithographic patterning may further include developing the photoresist after exposure and selectively removing unexposed portions of the photoresists. This may create openings in the stack for etching of the layers below but may protect the structure to be transferred into the layers below, e.g., the top electrode structure to be transferred into the third layer 1103 comprising the second superconductor and optionally further into the second layer 1102 comprising the insulator.

Portions of the third and second layer 1103, 1102 which may not be protected by the remaining resist 1110 may be removed in step (d), e.g., by a selective etch step or sequence of etch steps. This may transfer the top electrode structure to the third layer 1103 and further into the second layer 1102. Combining the selective removal of material of the third and second layer 1103, 1102 may mean that aligned structures for the top electrode and tunnel barrier of the vertical Josephson junction may be obtained with a single lithographic alignment step. In embodiments, the same or a different etchant may be used to first selectively remove material from the third layer 1103 and then continue to selectively removing material from the second layer 1102 too. The choice of the etchant or sequence of etchants generally may depend on the material choices for the second superconductor and insulator in these two layers.

In the following steps (e) to (f), the remainder of the first resist 1110 may be stripped off and a second photoresist layer 1111 may be applied to the stack and lithographically patterned to define the structures for the first layer 1101. The bottom electrode and the readout resonator with coupling head are structures that may be formed in the first layer 1101 comprising the first superconductor. Other portions of the readout circuit may be defined at the same time as the resonator. In embodiments in which the ground contact region, e.g., ground plane, is coplanar with the bottom electrode, the ground plane structure may be defined lithographically in steps (e) to (f). Lithographic patterning of the second resist layer 1111 may be performed similarly to previous step (c). The first resist 1110 and the second resist 1111 may have the same or different compositions. In embodiments using e-beam writing techniques, a positive tone resist may reduce the writing time.

Portions of the first superconductor in the first layer 1101 that are not protected by the remaining resist 1111 may be selectively removed in step (g), e.g., by a selective etch step or sequence of etch steps. This may transfer the bottom electrode structure, the ground plane structure and the readout circuit structure (including the readout resonator and coupling head structures) to the first layer 1101. Stripping off the remaining resist 1111 from the processed multilayer stack may yield a quantum circuit as shown in the cross-section of FIG. 10.

Only removal and no addition of material may be used to obtain quantum circuits in accordance with embodiments of the invention. Moreover, as little as two lithographic patterning and alignment steps may be required. A prefabricated multilayer material stack with precisely deposited/formed layers and little to no significant surface and/or interface defects may be used.

It is possible to over-etch the first layer 1101 in step (g), i.e., continue etching through the top surface and into the underlying substrate 1140, such that the structures for the first layer 1101 are also partially transferred into the substrate 1140. This may allow corresponding pedestals to form in the substrate that support and superelevate the structures of the first layer 1101 with respect to the exposed upper surface of the underlying substrate (e.g., the bottom wall of the gap region 102 in the quantum circuit 100 of the first embodiment). Combining the selective removal of material of the first layer 1101 and the selective, partial removal of substrate material may mean that aligned structures may be obtained in these layers with just a single lithographic alignment step. In embodiments, the same or a different etchant may be used to first selectively remove material from the first layer 1101 and then continue selectively removing material from the substrate 1140 too. The choice of the etchant or sequence of etchants may depend on the material choices for the second superconductor and insulator in these two layers.

In a variant of the manufacturing method, the structures for the first layer 1101, e.g., the bottom electrode, ground contact region and readout circuit structures, may be defined in the first resists 1110 and subsequently transferred to the first layer 1101 by selectively removing (e.g., etching away) corresponding material in the layers 1102, 1103 above. The second lithographic patterning step related to the second resist 1111 may then be used to define and protect the structures for the top electrode and the tunnel barrier in the third and second layer, respectively. This way, excess material in the third and second layer 1103, 1102 that does not belong to the top electrode and tunnel barrier structure may be removed to expose the coupling portion, ground plane and readout circuit within the first layer 1101.

The above illustration and description are to be considered illustrative or exemplary and not restrictive. Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. Any reference signs in the claims should not be construed as limiting the scope.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A quantum circuit comprising:
a bottom electrode formed in a first superconducting material layer, wherein the bottom electrode comprises a contact portion and a coupling portion;
a top electrode formed in a second superconducting material layer;
a vertical Josephson junction formed over a substrate, wherein the Josephson junction comprises the contact portion of the bottom electrode, a tunnel barrier, and the top electrode;
a transmon qubit comprising the vertical Josephson junction and a shunt capacitor formed by the top electrode and the contact portion of the bottom electrode as shunt capacitor plates; and
a readout circuit capacitively coupled to the bottom electrode through the coupling portion, wherein the readout circuit comprises a coupling head, wherein the coupling portion is fitted into a recess formed in the coupling head, wherein the top electrode of the vertical Josephson junction is configured as a floating electrode.

2. The quantum circuit of claim 1, wherein the readout circuit comprises a readout resonator, and wherein an end portion of the readout resonator comprises the coupling head of the readout circuit.

3. The quantum circuit of claim 2, wherein at least the readout resonator of the readout circuit is formed in the first superconducting material layer.

4. The quantum circuit of claim 1, further comprising a ground contact region adjacent to the vertical Josephson junction, wherein the ground contact region is formed in the first superconducting material layer or in a third superconducting material layer atop the second superconducting material layer.

5. The quantum circuit of claim 4, further comprising:
a gap that separates the ground contact region from sidewalls of the vertical Josephson junction, wherein the gap has a width of at most 100 nm in a normal direction to the sidewalls.

6. The quantum circuit of claim 1, wherein the recess in the coupling head is formed as a receiving slot with respect to the coupling portion of the bottom electrode.

7. The quantum circuit of claim 1, wherein the vertical Josephson junction has a characteristic junction length along a first direction parallel to the substrate and has a characteristic junction width along a second direction parallel to the substrate, wherein the second direction is perpendicular to the first direction, and wherein the ratio of characteristic junction width to characteristic junction length is at most 0.02.

8. The quantum circuit of claim 1, wherein the vertical Josephson junction has a junction area of size ‘A’ and a junction perimeter of length ‘P’, and wherein P²≥200*A.

9. The quantum circuit of claim 1, further comprising:
a ground contact region adjacent to the vertical Josephson junction, wherein the vertical Josephson junction has an oblong shape of width ‘w’ and area ‘A’; and
a gap separating the ground contact region from the sidewalls of the vertical Josephson junction having a gap width ‘G’, wherein G*w²/A<1 nm.

10. The quantum circuit of claim 1, wherein the first and second superconducting material layers comprise aluminum.

11. The quantum circuit of claim 1, wherein the vertical Josephson comprises a tunnel barrier, and wherein the tunnel barrier is formed in a dielectric layer.

12. The quantum circuit of claim 1, further comprising:
a ground contact region adjacent to the vertical Josephson junction, wherein the ground contact region surrounds the contact portion of the bottom electrode.

13. The quantum circuit of claim 1, wherein sidewalls of the vertical Josephson junction are free of deposited dielectric residuals.

14. The quantum circuit of claim 1, wherein sidewalls of the tunnel barrier interface air or vacuum.

15. A method of manufacturing a quantum circuit, comprising:
providing a multilayer material stack comprising a first superconducting material, a dielectric layer, and second superconducting material on a substrate;
forming a bottom electrode in the first superconducting material, wherein the bottom electrode comprises a contact portion and a coupling portion;
forming a top electrode in the second superconducting material;
forming a transmon qubit, wherein the transmon qubit comprises a vertical Josephson junction and a shunt capacitor, wherein the vertical Josephson junction comprises the contact portion of the bottom electrode, a tunnel barrier formed in the dielectric layer, and the top electrode, and wherein the shunt capacitor is formed by the top electrode and the contact portion of the bottom electrode as shunt capacitor plates; and
capacitively coupling a readout circuit to the bottom electrode, wherein the coupling comprises fitting the coupling portion of the bottom electrode into a recess formed in a coupling head of the readout circuit, wherein the top electrode of the vertical Josephson junction is configured as a floating electrode.

16. The method of claim 15, further comprising:
adjacent to the vertical Josephson junction, forming a ground contact region in the first superconducting material layer or in a third superconducting material layer atop the second superconducting material layer.

17. The method of claim 15, wherein forming the top electrode comprises:
patterning and selectively removing material from the second superconducting material layer.

18. The method of claim 17, wherein forming the top electrode further comprises:
patterning and selectively removing material from the dielectric layer.

19. The method of claim 15, wherein forming the bottom electrode comprises:
patterning and selectively removing material from the first superconducting material layer.

20. The method of claim 19, wherein forming the bottom electrode further comprises:
patterning and selectively removing material from the substrate.
